(19) United States
(12) Patent Application Publication
(10) Pub. No.: US 2008/0079054 A1
(43) Pub. Date: Apr. 3, 2008

(54) NONVOLATILE MEMORY DEVICE AND METHOD OF MANUFACTURING THE SAME

(75) Inventor: Suk Goo Kim, Anyang-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,608

(22) Filed: Dec. 29, 2006

(30) Foreign Application Priority Data
Jun. 30, 2006 (KR) 2006-60597

(51) Int. Cl. H01L 29/76

(52) U.S. Cl. 257/314

(57) ABSTRACT

A semiconductor device includes a graded SiGe layer and a strained Si layer that are formed on a Si surface. A gate is formed on the strained Si layer. The gate includes a tunnel oxide layer, a floating gate, a dielectric layer and a control gate is formed.

### BACKGROUND OF THE INVENTION

The present invention relates to a nonvolatile memory device and more particularly to a nonvolatile memory device and a method of manufacturing in which the program speed can be enhanced without increasing the program voltage.

Semiconductor memory devices used to store data are generally classified into volatile and non-volatile memory devices. Information stored in volatile memory devices is lost when power is turned off, whereas information stored in nonvolatile memory devices is retained even after power is turned off.

Nonvolatile devices are classified into two types depending on the structure of the memory cell; a floating gate type memory device, such as a general flash memory device, and a floating trap type memory device, such as a Silicon-Oxide-Nitride-Oxide-Silicon (SONOS) memory device.

In a general flash memory device a floating gate (e.g., a conductive material) is isolated by a tunnel oxide layer and a dielectric layer and formed between a semiconductor substrate and a gate electrode. When programming, the general flash memory device uses the floating gate to store charges in free carrier form. Accordingly, if failure occurs in a part of the tunneling insulating layer that isolates the floating gate from the substrate, the charges stored in the floating gate may be lost. Accordingly, the general flash memory device requires a relatively thick tunnel oxide layer compared with the SONOS memory device.

In contrast, when programming the SONOS memory device, charges are stored in a deep level trap, which is isolated within an insulating charge storage layer disposed between the gate electrode and the semiconductor substrate. This allows the SONOS memory device to have a thin tunnel oxide layer compared with the common flash memory device. Accordingly, the SONOS memory device can operate with a low gate application voltage of 5 to 10 V and allows higher integration of devices.

The SONOS memory device generally includes a silicon layer having a channel region formed therein, an oxide tunneling layer, a nitride charge trapping layer, an oxide blocking layer, and a polysilicon layer for a gate electrode. The layers are collectively referred to as “SONOS”.

Furthermore, the flash memory device of the nonvolatile memory devices is largely classified into NAND or NOR flash memory devices depending on the string structure of the cell array region. The NAND flash memory device represents a high level of integration but has a low cell current, compared with the NOR flash memory device (that is, the program speed of the NAND flash memory device is about 300 μs/512 Byte, which is 30 times slower than that of the NOR flash memory device).

The advantage of the NAND flash memory device is that cells of one page are programmed at the same time and cell-by-cell threshold voltage (Vt) optimization is possible, but the program speed is decided by the cell with the slowest program speed within one page. The program speed can be increased by raising the program voltage, but this leads to an over-program problem.

Accordingly, there is a need for a method of increasing the program speed without raising the voltage in order to fabricate nonvolatile memory devices requiring both high integration and high speed.

### SUMMARY OF THE INVENTION

Accordingly, embodiments of the present invention relate to a nonvolatile memory device and a method of manufacturing the same, in which the program speed can be increased without increasing the program voltage.

A nonvolatile memory device according to an aspect of the present invention includes the steps of; forming a graded SiGe layer on a semiconductor substrate; forming a strained Si layer on the graded SiGe layer; and forming a gate on the strained Si layer which is composed of a tunnel oxide layer, a trap nitride layer, a blocking oxide layer and a gate electrode.

### BRIEF DESCRIPTION OF THE DRAWINGS

FIGS. 1A to 1C are sectional views illustrating a method of manufacturing a SONOS memory device according to an embodiment of the present invention.

### DESCRIPTION OF SPECIFIC EMBODIMENTS

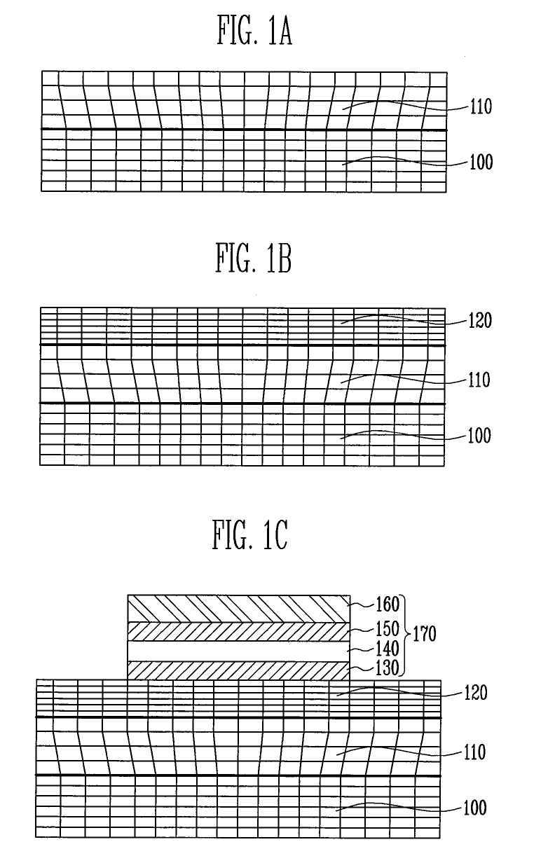

Referring to FIG. 1A, a graded SiGe layer 10 is selectively formed in a predetermined region on a semiconductor substrate 100 made of silicon (Si). The graded SiGe layer 110 may be formed to a thickness of 100 to 500 Å, and functions as a buffer layer between the silicon surface of the semiconductor substrate 100 and a strained Si layer to be formed in a subsequent process. The graded SiGe layer 110 is formed on the semiconductor substrate 100 by performing a first epitaxial growth process.

The first epitaxial growth process employs a Si source gas and a germanium (Ge) source gas. During the growth process, the concentration of the Ge source gas is gradually increased. Accordingly, the graded SiGe layer 110 has a gradually increasing ratio of Ge constituents. The desired ratio is determined by the amount of strain that needs to be applied to the strained Si layer of a subsequent process.

A typical SiGe alloy is represented by SixGe(1-x), where x is mole fraction. In the graded SiGe layer 110, the ratio of Si and Ge mole fraction is 0.8:0.2 so that dislocation does not occur. That is, x=0.8. In other words, the graded SiGe layer 110 is a layer in which Si with a lattice constant distance of 5.43 Å and Ge with a lattice constant distance of 5.62 Å are mixed. Accordingly, the size of the crystalline lattice of the graded SiGe layer 110 is increased about 4% by lattice constant difference of Si and Ge.

Referring to FIG. 1B, Si is grown on the graded SiGe layer 110 by performing a second epitaxial growth process. A strained Si layer 120 caused by the deformation of Si is then formed. The strained Si layer 120 may be formed to a thickness of 500 to 1000 Å.

In more detail, the strained Si layer 120 is formed because a layer of Si between the Si and SiGe junctions is deformed due to the difference in the lattice constant distance between the Si grown on the strained Si layer 120 and the SiGe of the graded SiGe layer 110. In this case, the strained Si layer 120 includes Ge atoms (Ge has a lattice constant greater than Si atoms) and therefore has a lattice width greater than that of typical Si. For example, the lattice width of the strained Si layer 120 is 5.62 Å or greater.

In particular, the deformation of the Si layer between the Si and SiGe junctions is accelerated since the crystalline lattice of SiGe is great. Accordingly, the degree of deformation of the Si layer can be controlled by controlling the amount of Ge in the SiGe layer (i.e., the concentration of Ge controls the deformation and the change in bandgap energy). Such deformation is caused by a deformed silicon bandgap (Eg=0.9 eV), which reduces factors hindering the mobility of electrons and holes within a material.

Consequently, the strained Si layer 120 increases the lattice constant to decrease an electric field, leading to an increased mobility of electrons and holes. As a result, a channel current can be improved by 10 to 35%.

Furthermore, an increase in the channel current results in an increased tunneling current trapped at a floating gate. Accordingly, the time needed for electrons to tunnel is reduced, increasing the program speed.

Improvement in the flow of current as described above means an increase in the speed of transistors. If the flow of current is improved by about 30%, voltage requirements can be reduced in half.

Accordingly, if the strained Si layer 120 is employed according to the present invention, the program speed can be increased without increasing the program voltage, and an over-program problem can be avoided.

Referring to FIG. 1C, a tunnel oxide layer, a trap nitride layer, a blocking oxide layer and a polysilicon layer are deposited on the semiconductor substrate 100 including the strained Si layer 120 by performing Chemical Vapor Deposition (CVD) (e.g., Low Pressure CVD (LPCVD). They are then patterned using a mask, forming a tunnel oxide layer 130, a trap nitride layer 140, a blocking oxide layer 150 and a gate electrode 160. Together, these four layers form a gate 170 with a SONOS structure.

The tunnel oxide layer 130 and the blocking oxide layer 150 are composed of SiO₂, and the trap nitride layer 140 is composed of SiNx. Accordingly, the trap nitride layer 140 can operate by using the trap level of the nitride layer. The gate electrode 160 is formed using a conductive material, such as a polysilicon layer, a metal layer or a combination of both, and functions as a switch.

The blocking oxide layer 150 serves as an insulator that isolates the trap nitride layer 140 and the gate electrode 160 from each other. That is, the tunneling current trapped at the trap nitride layer 140 can be increased by forming the strained Si layer 120 according to the present invention, and the time required for electrons to tunnel is reduced. Accordingly, a SONOS memory device having both high integration and high speed, is completed.

Though not illustrated in the drawings, the etch mask for forming the gate 170 employs a photomask by a photolithography process and photo and etch process. The photomask formation method is well known in the art, and will not be described further.

The SONOS memory device has been described as an example for convenience of description. However, the present invention may be applied to other memory devices, e.g., conventional flash memory devices having floating gates. In other words, the graded SiGe layer and the strained Si layer are sequentially formed on the Si surface according to the present invention. The gate is sequentially formed with a tunnel oxide layer, a floating gate, a dielectric layer and a control gate, and is then applied to a flash memory device. Accordingly, the present invention can enhance the program speed of a flash memory device without increasing the program voltage. Furthermore, the fabrication method of the present invention can achieve high integration and high speed in nonvolatile memory devices and can solve the over-program problem.

Although the foregoing description has been made with reference to the various embodiments, it is to be understood that changes and modifications of the present patent may be made by those skilled in the art without departing from the spirit and scope of the present invention. For example, the present invention can be applied to DRAMs or other types of semiconductor devices. The scope of the invention should be interpreted using the appended claims.

What is claimed is:

1. A nonvolatile memory device, comprising:
a graded SiGe layer formed over a semiconductor substrate;
a strained Si layer formed over the graded SiGe layer; and
a gate structure formed over the strained Si layer.

2. The nonvolatile memory device of claim 1, wherein the graded SiGe layer is formed directly on the semiconductor substrate, and the strained Si layer is formed directly on the graded SiGe layer, and wherein the strained Si layer has a lattice width of at least 5.62 Å.

3. The nonvolatile memory device of claim 1, wherein the strained Si layer is formed to a thickness of 500 to 1000 Å.

4. The nonvolatile memory device of claim 1, wherein the graded SiGe layer comprises SixGe(1-x), where x is mole fraction.

5. The nonvolatile memory device of claim 1, wherein the graded SiGe layer includes Si and Ge whose mole fraction is 0.8:0.2.

6. The nonvolatile memory device of claim 1, wherein the graded SiGe layer is formed to a thickness of 100 to 500 Å.

7. The nonvolatile memory device of claim 1, wherein the semiconductor substrate is a Si substrate.

8. The nonvolatile memory device of claim 1, wherein the gate structure includes a tunnel insulating layer, a trapping layer, a blocking layer and a gate electrode.

9. The nonvolatile memory device of claim 8, wherein the tunnel insulating layer is oxide, the trapping layer is nitride, and the blocking layer is oxide.

10. The nonvolatile memory device of claim 1, wherein the gate structure includes a tunnel insulating layer, a floating gate, a dielectric layer and a control gate.

11. A method of manufacturing a nonvolatile memory device, the method comprising:
forming a graded SiGe layer over a semiconductor substrate;
forming a strained Si layer over the graded SiGe layer; and
forming a gate structure over the strained Si layer.

12. The method of claim 11, wherein the graded SiGe layer is formed by an epitaxial growth process.

13. The method of claim 11, wherein the graded SiGe layer includes Si and Ge whose mole fraction is 0.8:0.2.

14. The method of claim 12, wherein the epitaxial growth process uses a Si source gas and a Ge source gas.

15. The method of claim 14, wherein the epitaxial growth process includes gradually increasing a concentration of the Ge source gas.

16. The method of claim 11, wherein the strained Si layer is formed by growing silicon by the epitaxial growth process and deforming the silicon layer.

17. The method of claim 11, wherein the strained Si layer has a lattice width of at least_{—}4%.

18. The method of claim 11, wherein the gate structure includes a tunnel insulating layer, a trapping layer, a blocking layer and a gate electrode.

19. The nonvolatile memory device of claim 11, wherein the tunnel insulating layer is oxide, the trapping layer is nitride, and the blocking layer is oxide.

20. The method of claim 11, wherein gate structure includes a tunnel insulating layer, a floating gate, a dielectric layer and a control gate.
